(19) United States
(12) Patent Application Publication
(10) Pub. No.: US 2026/0098916 A1
(43) Pub. Date: Apr. 9, 2026

(54) SYSTEM AND METHOD FOR OFF-CONDUCTOR ELECTRIC FENCE MONITORING

(71) Applicant: SensorTech, LLC, Wichita, KS (US)

(72) Inventors: Gerald A. Rues, Wichita, KS (US); Andrew Trefethen, Wichita, KS (US); Chad E. Bodecker, Benton, KS (US); Christopher A. Howell, Wichita, KS (US)

(73) Assignee: SensorTech, LLC, Wichita, KS (US)

(21) Appl. No.: 19/352,208

(22) Filed: Oct. 7, 2025

Related U.S. Application Data
(60) Provisional application No. 63/705,260, filed on Oct. 9, 2024.

(51) Int. Cl. G01R 31/52; A01K 3/00; G01R 31/54; H02H 3/20

(52) U.S. Cl. CPC G01R 31/52; A01K 3/005; G01R 31/54; H02H 3/20

(57) ABSTRACT

An off-line monitoring unit and method for sensing electrical disruptions on an electric fence conductor includes a non-conductive housing, a broad frequency pulse detector housed therein, a controller, and a communication device. The broad frequency pulse detector can include an antenna spaced apart from and positioned within a predetermined distance range away from the conductor being monitored. The controller is coupled to receive current induced on the antenna by high voltage on the conductor and, based on the received current, changes a state of the controller indicating the high voltage stopped inducing the current on the antenna for a predetermined length of time. The communication device, in response to the change of state of the controller, transmits a notification signal to a local notification device or a remote computing device that the conductor is off or inactive.

### CROSS-REFERENCE TO RELATED APPLICATIONS

The current patent application is a non-provisional utility patent application which claims priority benefit, with regard to all common subject matter, of earlier-filed U.S. Provisional Application Ser. No. 63/705,260; titled “ELECTRIC FENCE MONITORING SYSTEM”; and filed October 9, 2024. The Provisional Application is hereby incorporated by reference, in its entirety, into the current patent application.

### BACKGROUND OF THE INVENTION

Electrified Fences are used to deter boundary crossing by animals. Used often in livestock farming, they provide an effective and cheap alternative to large permeant fence enclosures. Those who use electric fences often must manually monitor them for breaks and unintentional groundings. An unmanaged break or grounding will allow the livestock to leave the intended perimeter. The outcome is frequently time wasted rounding up the livestock, and sometimes bodily injury or property damage.

To remotely monitor whether or not there is a break in the electric fence, on-line monitors have been designed to hang on the electrified wire or conductor. The on-line monitors typically use an inductive probe to determine the current running inside the conductor / wire and surface probes to determine the resistance per meter of the conductor. Using these parameters, the on-line monitor can calculate voltage using Ohm’s Law V-IR. The on-line monitors need to directly contact the conductor with conductive probes, and hanging of non-trivial amounts of weight onto the conductor can cause some problems over time. For example, the weight and surface area hanging on the conductor increases the likelihood of a break due to repeated stresses resulting from bounding and swaying in the wind, inadvertent brushes of livestock, or the like. Livestock can be curious and seek to understand the nature of these on-line monitors, causing damage to the unit, the line, or both. Finally, the on-line nature of these monitors can increase the chances of the fence being inadvertently grounded (e.g., via a long piece of wet grass), which can dramatically reduce the voltage along the line.

### SUMMARY OF THE INVENTION

Embodiments of the current invention address one or more of the above-mentioned problems and provide a distinct advance in the art of electric fence monitoring. In some embodiments, an off-line monitor that can determine if a wire or conductor of an electric fence has a break or inadvertent ground between an electric energizer or charger and the off-line monitoring unit, and can advantageously make such determinations without hanging an entire conspicuous on-line monitoring unit off the conductor of the electric fence.

In one embodiment, an off-line monitoring unit for sensing electrical disruptions on a conductor of an electric fence includes a non-conductive housing, a broad frequency pulse detector housed therein or attached thereto, a controller, and a communication device. The broad frequency pulse detector can include an antenna to be located within a predetermined distance range away from the conductor being monitored. The controller is coupled to receive current induced on the antenna by high voltage on the conductor and based on the received current, changes a state of the controller indicating the high voltage dropped below a predetermined voltage or stopped inducing the current on the antenna for a predetermined length of time. The communication device, in response to the change of state of the controller, transmits a notification signal to a local notification device or a remote computing device that the conductor is off or inactive.

In another embodiment, a system for electrifying and monitoring an electric fence includes a conductor suspendable between two structures, a charger inducing high voltage down the conductor, and an off-line monitoring unit. The off-line monitoring unit includes a non-conductive housing, a broad frequency pulse detector housed in or attached to the housing, a controller electrically coupled with the broad frequency pulse detector, and a communication device electrically coupled with the controller. The broad frequency pulse detector can include an antenna located within a predetermined distance range away from the conductor. The antenna is positioned such that the high voltage on the conductor induces current flow on the antenna. The controller receives the current flow induced on the antenna and indicates an absence of the high voltage for a predetermined length of time based on the current received from the antenna. The communication device detects the indication from the controller of the absence of the high voltage for the predetermined length of time and, in response to this detection, transmits a notification signal to a local notification device or a remote computing device indicating that the conductor is off, inactive, or that the high voltage being induced on the conductor is below a predetermined voltage.

In yet another embodiment, a method for monitoring a conductor of an electric fence includes a step of using an antenna to detect high voltage induced on the conductor. The antenna is spaced apart and proximate to the conductor such that the high voltage on the conductor induces current flow on the antenna. The method also includes the steps of sending the current flow induced on the antenna to a controller and determining with the controller that the high voltage has ceased inducing the current flow on the antenna for a predetermined length of time. The method additionally includes the steps of indicating, via the controller to a communication device, that the conductor is off or inactive based on the determination that the high voltage has ceased inducing the current flow on the antenna for the predetermined length of time, and transmitting with the communication device a notification signal to a local notification device and/or a remote computing device that the conductor is off or inactive.

This summary is provided to introduce a selection of concepts in a simplified form that are further described below in the detailed description. This summary is not intended to identify key features or essential features of the claimed subject matter, nor is it intended to be used to limit the scope of the claimed subject matter. Other aspects and advantages of the current invention will be apparent from the following detailed description of the embodiments and the accompanying drawing figures.

### BRIEF DESCRIPTION OF DRAWINGS

Embodiments of the current invention are described in detail below with reference to the attached drawing figures, wherein:

FIG. 1 is a schematic drawing of a system for electrifying and monitoring a conductor of an electric fence in accordance with embodiments herein;

FIG. 2 is a schematic drawing of an off-line monitoring unit of the system of FIG. 1 in accordance with embodiments herein;

FIG. 3 is an exploded perspective view of the off-line monitoring unit of FIG. 2 configured for mounting onto a t-shaped post, in accordance with embodiments herein;

FIG. 4 is a perspective view of the off-line monitoring unit of FIG. 2 mounted onto a wooden post, in accordance with embodiments herein;

FIG. 5 is an electrical circuitry schematic of a broad frequency pulse detector, a controller, and other circuitry of the off-line monitoring unit of FIG. 2, in accordance with embodiments herein; and

FIG. 6 is a flow chart of a method for off-line monitoring of a conductor of an electric fence in accordance with embodiments herein.

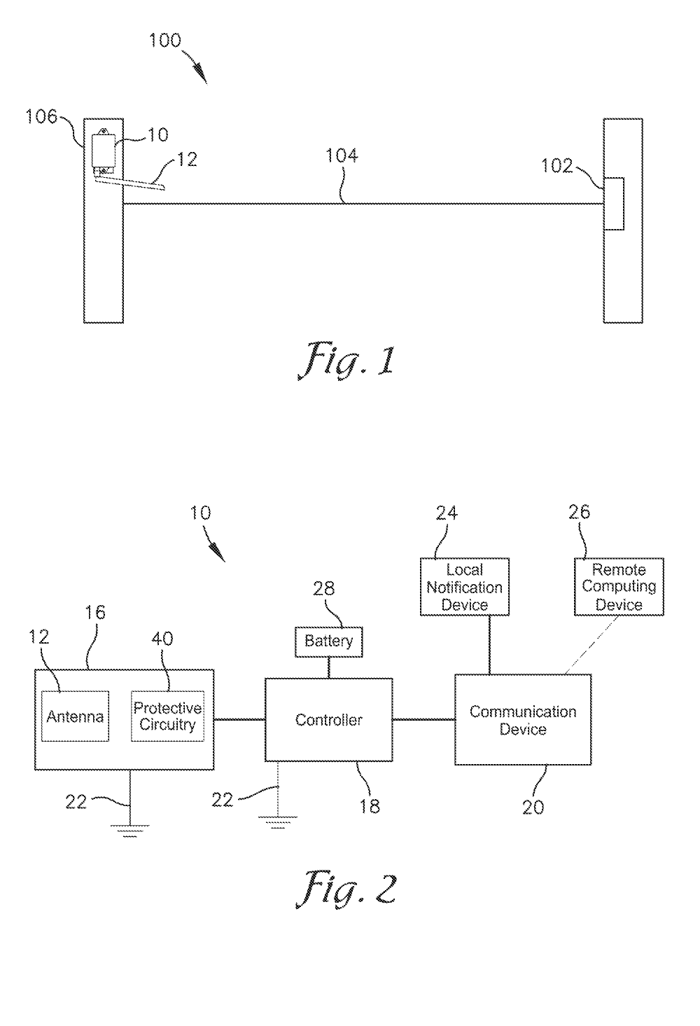

The drawing figures do not limit the current invention to the specific embodiments disclosed and described herein. The drawings are not necessarily to scale, emphasis instead being placed upon clearly illustrating the principles of the invention.

### DETAILED DESCRIPTION OF THE INVENTION

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the current invention. The following detailed description is, therefore, not to be taken in a limiting sense. The scope of the current invention is defined only by the appended claims, along with the full scope of equivalents to which such claims are entitled.

Electric fences operate by periodically sending from an energizer or charger 102 a high voltage signal or pulse down a conductor 104 such as a wire of the electric fence suspended between two structures such as fence posts 106. This signal or pulse can be any changing current / voltage that will generate EMF. Specifically, AC voltage or pulsed DC voltage, as well as any number of non-continuous DC transmissions can each induce a short electromagnetic field (EMF) spike or EMF pulse in the area surrounding the conductor detectable out to several yards with sensitive equipment. The strength of this field is strongly correlated with the voltage of the conductor 104 or wire. Thus, in one or more embodiments described herein, a system 100 for electrifying and monitoring a conductor of an electric fence can include the charger 102, the conductor 104, the fence posts 106, and/or an off-line monitoring unit 10. The off-line monitoring unit 10 comprises an antenna 12 used as a broad-spectrum energy harvester. Specifically, high voltage signals or pulses on the conductor 104 or wire of the electric fence induce a small current inside the antenna 12, causing a voltage spike or pulse to enter the unit 10. This voltage spike or pulse can be processed in order to determine a present state of the conductor 104 of the electric fence (e.g., on or off, active or inactive), as described in more detail below.

Electric fences or other such conductors or wires supported between non-conductive structures (e.g., the fence posts 106 with electric wires strung therebetween, electrical poles supporting powerlines, or the like) are described herein. Specifically, the structures or fence posts 106 may be wooden posts, metal posts or T-shaped posts, or other structures known in the art. The charger 102 may be any electric fence charger or energizer known in the art and is responsible for creating a powerful but safe shock that deters animals. The energizer or charger 102 is generally not designed to continuously electrify the conductor 104 (e.g., continuous DC voltage), but instead sends out continuous AC voltage signals or short, sharp timed pulses of electricity, ensuring safety for animals and humans who might accidentally touch the fence. In some example embodiments, high voltage pulses of 2,000 to 15,000 volts may be provided to the conductor 104, while keeping current or amperage relatively low. The conductor 104 may be any elongated, electrically conductive material, such as metal, and may include metal wires, electrical lines, electrical cables, metal poles, or the like.

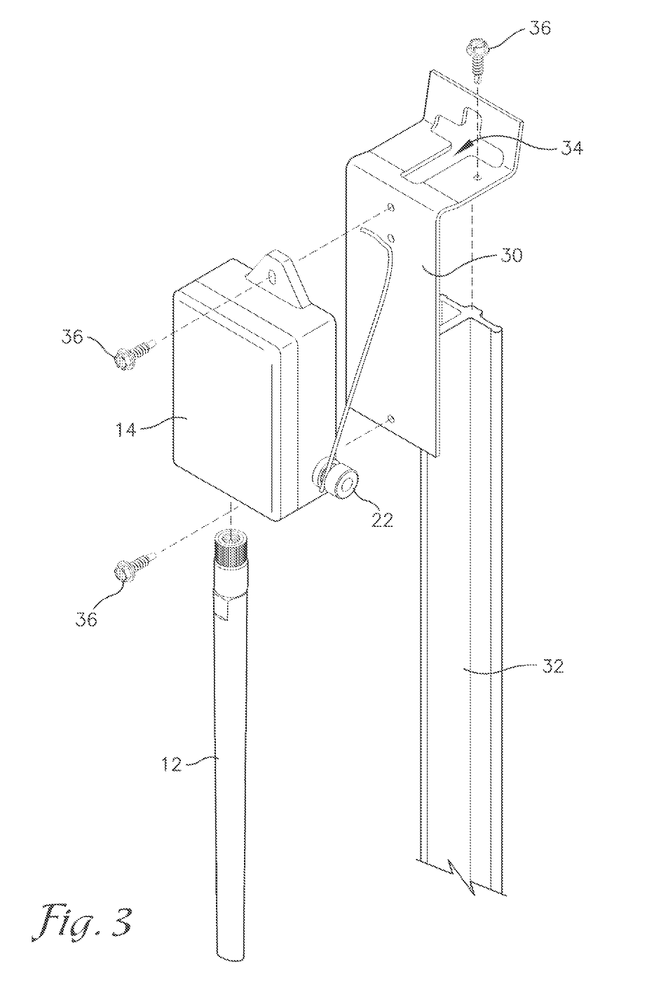

In one or more embodiments, the off-line monitoring unit 10 described herein may comprise a housing 14, a broad frequency pulse detector 16, a controller 18, and a communication device 20. In one or more embodiments, additional or alternative circuitry such as various wires, resistors, capacitors, diodes, transistors, microcontrollers, processors, or other circuitry known in the art for achieving the functions described herein can be used without departing from the scope of the invention. The unit 10 may also comprise at least one ground connection 22, as depicted in FIGS. 3-5, configured to be connected to any suitable ground source (e.g., a ground wire, T-post, step-in post, ground rod, or the like). In some embodiments, the off-line monitoring unit 10 further includes a local notification device 24, such as a speaker, a light, and/or an actuator configured to audibly or visually indicate current induced on the antenna 12 and/or to otherwise indicate whether or not the high voltage of the conductor 104 has dropped below a predetermined voltage threshold for a predetermined length of time (e.g., if high voltage pulses above a particular threshold are no longer detected by the antenna every few seconds), as later described herein. The local notification device 24 can be electrically coupled to the controller 18 and/or the communication device 20. Additionally or alternatively, the communication device 20 can be remotely coupled via wires or wireless communication means to a remote computing device 26, including any servers, processors, or the like, as later described herein. The unit 10 may also include a power source 28 for powering one or more of the controllers or other various circuitry and devices described herein.

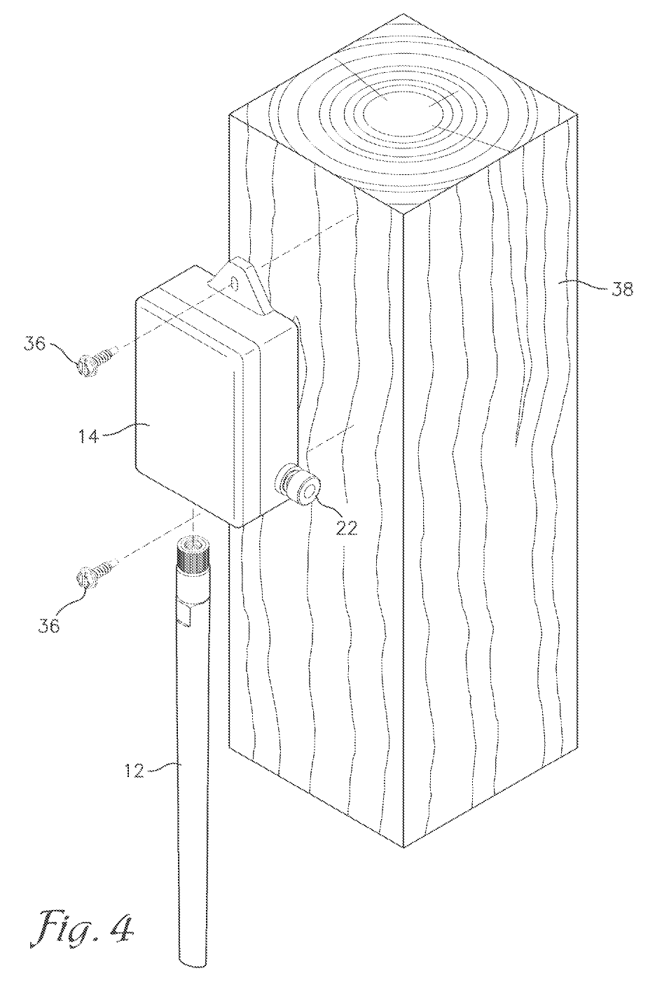

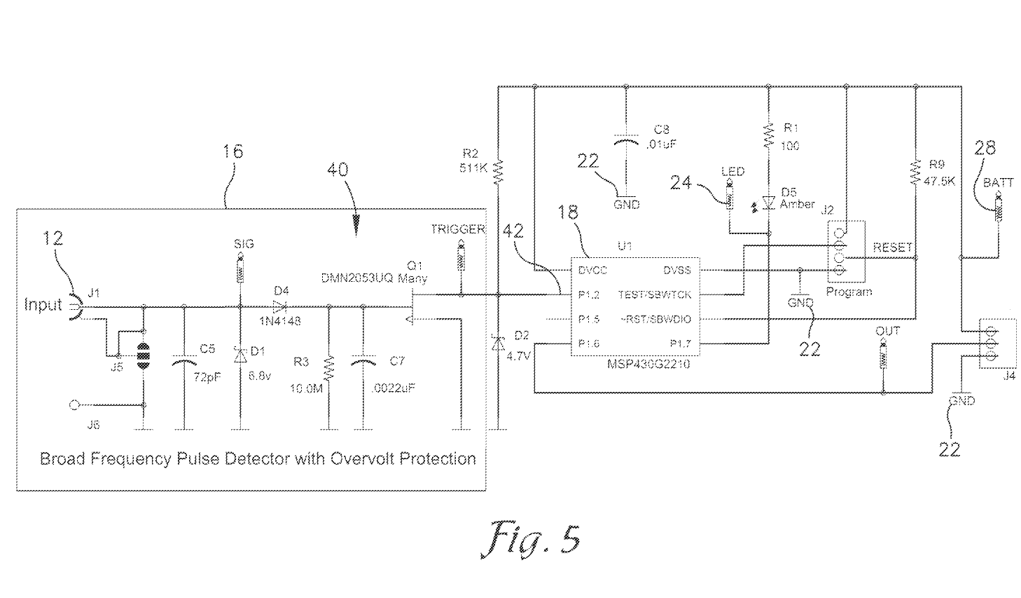

The housing 14, as depicted in FIGS. 3-4, may comprise any non-conductive rigid material and may provide protection from moisture and other environmental elements. In some embodiments, as depicted in FIG. 3, the housing 14 is attachable to and/or is integrally formed with a mounting bracket 30 or other mounting implements. For example, in some embodiments configured for attachment to a T-shaped post 32 supporting the wire or conductor 104, a bracket having a T-shaped opening 34 may be utilized. Specifically, the bracket 30 can be slid over the T-shaped post 32 via the T-shaped opening 34 and then the housing may be fastened (e.g., via fasteners 36) or otherwise affixed to the bracket. Alternatively, the housing may be screwed or otherwise fastened (e.g., via the fasteners 36) onto a wooden post 38, as depicted in FIG. 4, supporting the conductor 104 of the electric fence. However, other housing configurations may be utilized without departing from the scope of the invention. Furthermore, alternative structures for supporting the housing besides the fence posts can be used without departing from the scope of the invention, such as a dedicated housing support which does not support the conductor, a natural object (such as a tree within a desired distance away from the conductor), a nearby structure or building (such as a shed within a desired distance away from the conductor), an integrated ground stake that is unitary with the housing, or the like.

In some alternative embodiments, the non-conductive housing 14 may be configured to be hung from one of the conductors 104, providing a predetermined spacing between the antenna 12 and the conductor 104. For example, a plastic hanger can be used to hang the housing 14 and/or the antenna 12 onto the conductor 104. In this alternative embodiment where the antenna 12 is hung via a non-conductive material onto the conductor 104, in order to limit weight pulling on the conductor 104, other components of the unit 10 may be housed a distance away from the antenna 12 (e.g., mounted to a secondary housing installed on a secondary post or one of the posts supporting the conductor 104), which may be electrically coupled to the controller 18 and other components described herein via an elongated flexible shielded cable or the like.

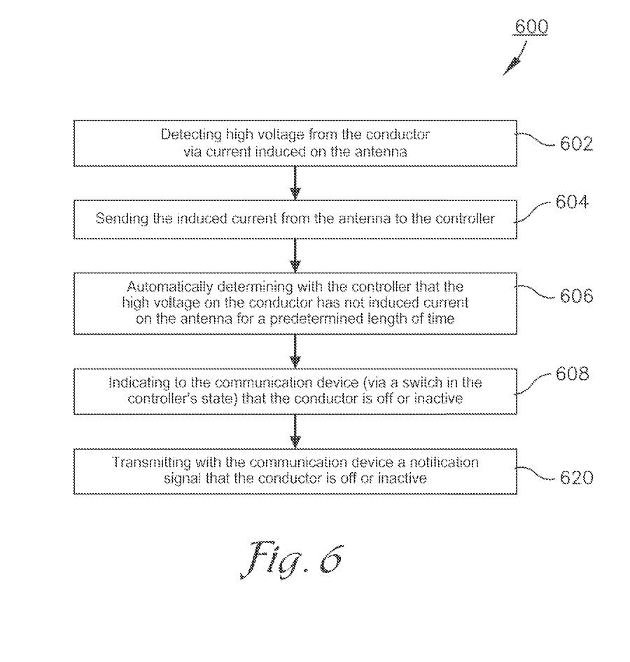

As depicted in FIGS. 2 and 5, the broad frequency pulse detector 16 can be housed in or attached to the housing 14 and comprises the antenna 12. The antenna 12 is configured to be located within a predetermined distance range away from the conductor 104 (e.g., the wire of the electric fence). The antenna 12 may serve as a broad-spectrum energy harvester. Specifically, raw high voltage signal or pulse detection as required by the method steps described herein may be accomplished by tapping into a freestanding antenna. The antenna 12 can be, for example, a true RF antenna, a unterminated wire, a long pcb trace, or the like. The antenna 12 may be configured such that broad spectrum RF emissions readily induce current flow on the antenna located within the conductor’s EMF field. In some embodiments, the antenna 12 can be reconfigurable or actuatable (relative to the non-conductive housing 14, for example) in order to be positioned close enough (e.g., a few inches, such as two (2) to six (6) inches away, two (2) to twelve (12) inches away, one (1) to two (2) feet away, or the like) to the conductor 104 and in an appropriate direction such that RF emissions induce current flow on the antenna 12. Other distances between the conductor 104 and the antenna 12 that are sufficient to induce current onto the antenna 12 may be used without departing from the scope of the invention. The terms “reconfigurable or actuatable” as used in regards to the antenna 12 herein can refer to the antenna 12 being made of or attached to a flexible material to permit manual pivoting of at least a portion of the antenna 12, or the antenna 12 can be pivotally secured to the housing via mechanical or electromechanical pivot fasteners for manual or powered adjustment to direct the antenna 12 toward the conductor. In other embodiments, the antenna 12 can be attached to (or supported by) a powered actuator that can be operated to automatically shift the antenna into the necessary proximity and/or direction (via rotation, sliding, or other techniques for repositioning and/or changing the location, position, or direction of an antenna). In some embodiments, the antenna 12 may be fixed a predetermined distance from the conductor 104 and within the electric field given off by the conductor 104 via the charger 102.

The broad frequency pulse detector 16 can further comprise protective circuitry 40 configured to convert the induced current from the antenna 12 into a useable signal for the controller 18. For example, in one or more embodiments, the protective circuitry 40 is a simple protection circuit and raw pulse energy from the antenna 12 is funneled through the simple protection circuit comprised of a reverse biased Zener diode to common and a forward biased rectifier diode, as depicted in FIG. 5. The Zener diode is thus configured to shunt energy above the reverse breakdown voltage to common, protecting upstream circuitry from overvoltage conditions. Furthermore, the rectifier diode is configured to only allow forward biased current into the upstream circuitry and protects from negative voltage conditions. In one or more embodiments, the protective circuitry may further include a transistor/mosfet. Specifically, the rectified pulse can be directed into the gate of the transistor/mosfet, which may be connected to an I/O pin 42 on a low power microcontroller (e.g., the controller 18). In some example embodiments, the gate of the transistor can be biased towards common via a pull-down resistor. In this configuration, when the gate of the transistor is excited, a strong signal is sensed by the microcontroller, the I/O pin 42 of which can be configured to cause a wake-up interrupt within the firmware.

As depicted in FIGS. 2 and 5, the controller 18 can comprise a microcontroller, microprocessor, one or more processing elements, memory, and/or other circuitry and processing devices known in the art, as described in more detail below. Specifically, FIG. 5 depicts the controller 18 as a microcontroller having the I/O pin 42 noted above and communicably coupled with the protective circuitry 40. When the microcontroller receives a wake-up interrupt, as described above (e.g., the gate of the transistor is excited), the microcontroller may be configured to respond by handling the wake-up interrupt and suitably updating a machine state of the microcontroller according to a desired output format and configured sense parameters.

In one example embodiment, the sense parameters may include the following: P = the minimum number of pulses within a sliding window that is equivalent to an “on” state, and T = the length of time that is within the sliding timer window. The microcontroller in this example embodiment may be further configured such that when the microcontroller receives a pulse interrupt, the microcontroller performs the equivalent of the following assessment: 1. cancel any waiting window timer interrupts; 2. add the current pulse and pulse time to an open list of pulses; 3. if there are more pulses in the open list than P, only the last P pulse records are kept; 4. if there are P pulses in the open list, the conductor’s state is changed to “ON” or “active” and necessary outputs are changed; 5. calculate an end of the timer window that starts from the earliest pulse record left in the open list; 6. set a wake-up window timer interrupt to execute at the end of the previously calculated window; and 7. the microcontroller goes back to sleep until a next interrupt (i.e., the pulse interrupt or the timer interrupt) is triggered.

In some embodiments, when the microcontroller receives the timer interrupt, the microcontroller may be configured to perform one or more steps of the following assessment: 1. remove the earliest pulse record from the current open list; 2. if there are less than P pulses left in the open list, the conductor’s state is changed to “OFF” or “inactive” and necessary outputs are changed; 3. if there is at least 1 pulse record left in the open list, a new wake-up timer window is set for the end of the window that starts from the earliest pulse left in the list; and 4. The microcontroller goes back to sleep until the next interrupt (i.e., the pulse interrupt or the timer interrupt) is triggered. Advantageously, the microcontroller can use the above-described interrupt driven algorithms to minimize power consumption of the unit 10.

Output from the controller 18 or microcontroller can be in many formats. For example, in one or more embodiments, a simple binary signal may be output from the microcontroller. The microcontroller outputs a HIGH signal when the conductor state is “ON” or “active” and a LOW signal when the conductor state is “OFF” or “inactive.” However, the output could swap the HIGH and LOW signal states, output differing sequences of bits, output consistently timed pulses at a prescribed frequency as long as the fence state remained “ON,” or even output a constant current signal such as an industry common 4-20ma scheme without departing from the scope of the invention.

In some embodiments, the controller 18 (e.g., the microcontroller in FIG. 5) and/or other circuitry associated therewith is configured (e.g., via firmware or the like) to convert the pulses sensed by the antenna 12 into a steady state voltage. For example, if the microcontroller via the antenna 12 is detecting the high voltage on the conductor 104 every second to three (3) seconds, the microcontroller may output a steady state voltage (e.g., three (3) volts or the like), and then if the microcontroller stops detecting that high voltage (i.e., no longer detects current induced onto the antenna), the microcontroller can be configured to change its output to an open circuit in response to a predetermined length of time passing without detecting the high voltage on the conductor. When that open circuit is detected by the communication device 20 and/or the circuitry associated therewith, as described below, a signal indicating the conductor state is “OFF” or “inactive” can be output via the communication device 20 to the local notification device 24 and/or the remote computing device 26.

Binary output is power efficient and sufficient for determining absence or presence of EMF pulses induced by the conductor’s high voltage. However, in some alternative embodiments, circuit alterations can be made to the broad frequency pulse detector 16 and/or the controller 18 to determine or estimate a voltage reading of the high voltage on the conductor 12. For example, the broad frequency pulse detector 16 may include a coulomb counter in parallel to the raw pulse detector and can thus be configured to measure the size of energy packets or current received by the antenna from the conductor (e.g., a wire of the electric fence). Via the coulomb counter, the current can be integrated over small time intervals to calculate the amount of charge (coulombs) that has flowed in each interval. In some embodiments, the coulomb counter can be queried by the microcontroller to retrieve a raw “count” from the antenna. In one or more embodiments, using output formats other than binary, this count can be passed to one or more upstream devices such as those described herein. The count can then be compared to a look-up table of calibrated values (via circuitry in the unit 10 or a remote unit or server as described herein) to determine the voltage reading of the high voltage on the conductor based on the EMF pulse that was detected via current induced on the antenna. Furthermore, in some example embodiments, the microcontroller can be programmed to use more power efficient output modes (e.g., the binary output described above) a majority of the time and swap to a format suitable for transmitting counts on a timetable compatible with power constraints. Alternatively, in place of a coulomb counter, a capacitor large enough to fully hold the rectified pulse can be discharged across a current-sense resistor to estimate the pulse energy content and suitable “counts” can be recovered that way.

The communication device 20 may comprise or be part of an upstream device configured for local or remote communication tasks and/or processing of information received from the controller 18. In some example embodiments, the upstream device may comprise the communication device 20, circuitry configured for further processing output from the controller 18, and/or can be electrically coupled to any device suitable to power the unit 10 (e.g., the power source 28). In one example embodiment, the upstream device comprises a component 7082 manufactured by SensorTech LLC headquartered in Wichita, Kansas. However, other such upstream components or communication devices may be used without departing from the scope of the invention. In some embodiments, the communication device 20 may comprise cellular, wi-fi, or other wireless or wired communication components without departing from the scope of the invention. Typical processing by the upstream device and/or communication device 20 may include, for example, off-site transmission via RF, wired, laser, or acoustic networks. Other processing requirements may include local assessments to monitor for situations that fall outside of expected parameters and reducing off-site communications to only those necessary to notify users of a change in state (e.g, conductor switches from active to inactive). For example, a cellular radio can make a call to a back end system or server and if that back end system (e.g., the remote computing device 26) or server detects an anomaly or receives a notification of an anomaly, that back end system or server can be configured to then send a notification to a remote user (e.g., a farmer) on their mobile phone or other electronic device. Tertiary processing may include local annunciation (playing a sound, illuminating an indicator, lamp, or light) via the local notification device 24. In some example embodiments, any monitoring device or binary monitor that can monitor an open or closed circuit (e.g., SCADA systems, PLCS, or the like) can be used in place of the upstream device and/or the communication device 20 described herein, particularly for embodiments where the controller 18 operates in a binary manner as described above.

The power source 28, as depicted in FIG. 2 and described herein, can comprise a battery or any other power source configured to power one or more components described herein. The unit 10 described herein may be configured for drawing a small amount of power (e.g., 30 micro-watts, plus or minus 10 micro-watts), providing for years-long average battery life for the power source or battery for the unit 10. Additionally or alternatively, in some embodiments the pulse of energy or EMF from the conductor may be harvested and captured as energy to use as the power source for the unit. Specifically, as the EMF pulse is wirelessly detected via the antenna, energy can be captured and stored via a rechargeable battery or the like. The unit 10 described herein can operate on a low voltage (e.g., 0.5 – 2.5 VDC), and the micro energy wirelessly captured off of the conductor over long periods of time can enable a longer lifespan of the unit. Additionally or alternatively, solar panels and/or solar cells can be used as the power source 28 described herein. For example, the solar panels or solar cells can be combined with the energy harvesting off of the conductor to power the unit 10 described herein.

In operation, using a tuned capacitance of the broad frequency pulse detector 16, a length of the EMF pulse received by the antenna 12 can be stretched out such that it can be sensed by the controller 18 (e.g., a digital processor or microcontroller). For example, the elongated pulse can cause an interrupt on the controller 18, and the controller 18, in response, can set its output state to “active” and then return to a sleep mode. If a time window of a predetermined length of time (e.g., 10 seconds) elapses without a pulse interrupting the sleep mode (e.g., waking up the controller), the controller 18 may be configured such that an internal timer goes off and resets the controller’s output state to “inactive.”

In some embodiments, the controller’s output state is read by the communication device 20 (e.g., a communications enabled monitoring unit such as those described above). The communication device 20 can be configured to send notification signals to a backend service (e.g., the remote computing device 26) hosted on a central server and/or to other remotely located electronic devices. In some example embodiments, when the output state from the controller 18 changes, and that change persists for a configurable or predetermined length of time, a notification signal is sent by the communication device 20 to the remote server and/or a remotely located electronic device. For example, when the notification signal is received by the backend service, the central server may be configured to determine if a user notification should be sent to a remote electronic device (e.g., a mobile phone, computer, tablet, or the like) based on the state of the off-line monitoring unit 10 (e.g., indicating the conductor 104 is active or inactive) and stored preferences set by a user for such notifications.

Off-site transmissions are undertaken to notify one or more users or parties not present of situations that require attention or indicate that the equipment is still functioning and powered. The unit 10 described above, for example, can communicate with a backend corresponding to a server running custom software that receives incoming data and takes actions based on that data. These actions can include calling a third party API to send notifications through SMS, Voice, RCS, FTP, Email, API hooks, or the like. However, other remote notification techniques and settings may be used without departing from the scope of the invention.

Advantageously, the off-line monitor unit described herein can determine if the conductor 104 (e.g., a wire of an electric fence) has a break or inadvertent ground between the electric energizer or charger 102 and the off-line monitoring unit 10 and can advantageously make such determinations without hanging an entire conspicuous on-line monitoring unit off the conductor 104 of the electric fence.

The flow chart of FIG. 6 depicts an exemplary method 600 for monitoring a conductor of an electric fence in more detail. According to some aspects of the present invention, this method may be used for off-wire detection or monitoring of a conductor or wire in applications other than an electric fence. In some embodiments, various steps may be omitted, or steps may occur out of the order depicted in FIG. 6 without departing from the scope of the technology as described herein. For example, two blocks shown in succession in FIG. 6 may in fact be executed substantially concurrently, or blocks may sometimes be executed in the reverse order depending upon the functionality involved; unless expressly stated otherwise or as may be readily understood by one of ordinary skill in the art.

In one or more embodiments, the method 600 includes a step of detecting a high voltage (e.g., via an EMF pulse) from the conductor 104, as depicted in block 602. Specifically, the antenna 12 may be spaced apart from and proximate to the conductor 104, positioned such that high voltage (e.g., from the charger 102) on the conductor 104 creates EMF pulses that induce current flow on the antenna 12. This may be accomplished, for example, by fixing the antenna 12 and/or the housing 14 thereof within a few inches (e.g., two (2) to ten (10) inches or two (2) inches to two (2) feet away from the conductor). The housing 14 of the unit 10 may be, for example, fixed to a post or other such structure supporting the conductor 10 of the electric fence. In some example embodiments, the detecting step in block 602 first involves fixing the non-conductive housing 14 supporting the antenna 12 onto a structure supporting the conductor 104, like the fence post 106 or wire post, and can further include physically actuating the antenna 12 relative to the non-conductive housing 14 until the antenna 12 is directed toward the conductor. This actuating can occur by moving the antenna 12 in a manual or automated manner without departing from the scope of the invention. Any of the method 600 steps described herein can also include or be preceded by grounding one or more of the broad frequency pulse detector 16, the controller 18, and/or the communication device 20.

The method 600 may further include a step of sending the induced currentfrom the antenna 12 to the controller 18, as depicted in block 604. As described above, the controller 18 or microcontroller may be configured to be in sleep mode until triggered by a signal from the antenna 12 and/or the protection circuitry 40 between the antenna 12 and the controller 18. For example, when the gate of the transistor is excited due to current induced on the antenna 12, a strong signal is sensed by one of the microcontroller’s I/O pins, causing a wake-up interrupt within the firmware.

In one or more embodiments, the method 600 further includes the steps of automatically determining with the controller 18 that a subsequent or next high voltage / EMF pulse has not been sensed by the antenna 12 for a predetermined length of time, as depicted in block 606, and indicating to the communication device 20 that the conductor 104 is off or inactive, as depicted in block 608, based on that determination that the next high voltage / EMF pulse has not been sensed by the antenna 12 for the predetermined length of time. In some example embodiments, these steps comprise receiving a plurality of pulse interrupts from the antenna 12 via the current induced on the antenna 12 and then receiving a timer interrupt that is internally triggered by the controller 18 in response to a predetermined length of time elapsing without the pulse interrupt being received by the controller 18 from the antenna 12. In some embodiments, when the microcontroller receives/detects a wake-up interrupt (via the induced current from the antenna), the microcontroller responds by handling the wake-up interrupt and suitably updating a machine state of the microcontroller according to a desired output format and configured sense parameters. In one or more embodiments, when a predetermined length of time passes without the wake-up interrupt, the microcontroller has an internal timer interrupt that triggers an output from the microcontroller indicating that the conductor’s state is “OFF” or “inactive.” Then the microcontroller goes back to sleep until the next interrupt (e.g., the pulse interrupt indicating that the conductor’s state has switched back to “ON” or “active”) is triggered. Advantageously, the microcontroller can use the above-described interrupt driven algorithms to minimize power consumption of the unit 10.

Output from the controller 18 or microcontroller can be in many formats. For example, in one or more embodiments, a simple binary signal may be output from the microcontroller. The microcontroller outputs a HIGH signal when the conductor state is “ON” or “active” and a LOW signal when the conductor state is “OFF” or “inactive.” However, the output could swap the HIGH and LOW signal states, output differing sequences of bits, output consistently timed pulses at a prescribed frequency as long as the fence state remained “ON” or even output a constant current signal such as an industry common 4-20ma scheme without departing from the scope of the invention. In some embodiments, the microcontroller and/or other circuitry associated therewith converts the EMF pulses sensed via the antenna 12 into a steady state voltage. For example, if the microcontroller via the antenna 12 is detecting the high voltage / EMF pulse on the conductor 104 every one (1) second to three (3) seconds, the microcontroller may output a steady state voltage (e.g., three (3) volts or the like), and then if the microcontroller stops detecting that pulse, the microcontroller will change its output to an open circuit. When that open circuit is detected by the communication device 20 and/or the circuitry associated therewith, a signal indicating the conductor state is “OFF” or “inactive” can be output via the communication device 20 to the local notification device 24 and/or the remote computing device 26. While some embodiments herein include the microcontroller’s firmware being configured to detect the induced current’s pulse and outputting a steady state voltage, in some alternative embodiments, the microcontroller’s firmware can be alternatively programmed to output different types of signals (e.g., TTL, on/off keying, voltage varying, SPI, I²C, etc.) without departing from the scope of the invention.

In one or more embodiments, the method 600 also includes a step of transmitting with the communication device 20 a notification signal that the conductor 104 is off or inactive, as depicted in block 610. The notification signal can, for example, be provided to the local notification device 24 and/or the remote computing device 26. In some embodiments, the notification signal (e.g., indicating that the conductor is off or inactive) is transmitted by the communication device 20 in response to the controller 18 receiving the timer interrupt. Additionally or alternatively, the communication device 20 can likewise transmit notification signals when the conductor 104 is detected via the antenna 12 and the controller 18 to have switched from the “OFF” or “inactive” state to the “ON” or “active” state without departing from the scope of the invention.

The method and unit 10 described above may be used for detecting anything that has discontinuities in power and/or a changing electric field, such as AC voltage on a conductor or DC voltage operating in a pulse fashion (e.g., generating the EMF spike or pulse that induces current on the antenna). The resulting EMF spikes or pulses can be detected using the method steps above and the unit 10 or system herein. In close enough proximity, activity on a network cable in use can be detected via the methods described herein, for example. In some use cases where an electric fence includes three different power sources and three different conductors, there may be a unit (e.g., the unit 10) per each conductor, with each unit individually communicating with users via the remote system described above. Furthermore, in some embodiments, a charger can be placed at a middle section of a fence wire or conductor extending in opposing directions from that installation location, and units like the unit 10 may be placed at opposing ends of the conductor, wire, or electrical line so that each portion of the conductor or fence wire between the charger and the ends is separately monitored. In other alternative embodiments, additional units like the unit 10 may be staggered at predetermined distances (e.g., every 100 yards or every 200 yards) along the conductor or fence wire such that the user or farmer can determine more precisely where the problem detected is located. The notifications described herein can be provided to one or more users or farmers and/or multiple other devices without departing from the scope of the invention.

Throughout this specification, references to “one embodiment,” “an embodiment,” or “embodiments” mean that the feature or features being referred to are included in at least one embodiment of the technology. Separate references to “one embodiment,” “an embodiment,” or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the current invention can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless expressly stated otherwise or as my be readily understood by one of ordinary skill in the art].

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

What is claimed is:

1. An off-line monitoring unit for sensing electrical disruptions on a conductor of an electric fence, the system comprising:
a non-conductive housing;
a broad frequency pulse detector housed in or attached to the housing and comprising an antenna configured to be located within a predetermined distance range away from the conductor;
a controller configured to receive current induced on the antenna by high voltage on the conductor and to, based on the received current, change a state of the controller indicating the high voltage dropped below a predetermined voltage or stopped inducing the current on the antenna for a predetermined length of time; and
a communication device configured to, in response to the change of state of the controller, transmit a notification signal to a local notification device or a remote computing device that the conductor is off or inactive.

2. The off-line monitoring unit of claim 1, wherein the antenna is configured such that RF emissions or an electromagnetic field (EMF) of the conductor induce current flow on the antenna.

3. The off-line monitoring unit of claim 1, further comprising the local notification device, wherein the local notification device includes one or more of a speaker, a light, or an actuator configured to output an audible or visual response in response to the change of state of the controller.

4. The off-line monitoring unit of claim 1, wherein at least a portion of the antenna is pivotable relative to the non-conductive housing to be redirected toward the conductor.

5. The off-line monitoring unit of claim 1, further comprising a protection circuit electrically coupled between the antenna and the controller and configured for protecting the controller from overvoltage conditions.

6. The off-line monitoring unit of claim 1, wherein the communication device comprises a wireless communication unit or a wired communication output.

7. The off-line monitoring unit of claim 1, further comprising an attachment bracket attachable to the non-conductive housing and configured to mount to the post supporting the conductor.

8. A system for electrifying and monitoring an electric fence, the system comprising:
a conductor suspendable between at least two structures;
a charger configured to induce high voltage down the conductor;
a non-conductive housing;
a broad frequency pulse detector housed in or attached to the housing and comprising an antenna located within a predetermined distance range away from the conductor, wherein the antenna is positioned such that the high voltage on the conductor induces current flow on the antenna;
a controller configured to receive the current flow induced on the antenna and indicate an absence of the high voltage for a predetermined length of time based on the current received from the antenna; and
a communication device configured to detect the indication from the controller of the absence of the high voltage for the predetermined length of time and, in response to this detection, transmit a notification signal to a local notification device or a remote computing device indicating that the conductor is off, inactive, or that the high voltage on the conductor is below a predetermined voltage.

9. The system of claim 8, further comprising the local notification device, wherein the local notification device includes one or more of a speaker, a light, or an actuator configured to output an audible or visual response when receiving the electric signal.

10. The system of claim 8, wherein the antenna is selectively pivotable relative to the non-conductive housing to be directed toward the conductor.

11. The system of claim 8, further comprising a protection circuit electrically coupled between the antenna and the controller and configured for protecting the controller from overvoltage conditions.

12. The system of claim 8, wherein the communication device comprises a wireless communication unit or a wired communication output.

13. The system of claim 8, further comprising an attachment bracket attachable to the non-conductive housing and configured to mount to one of the structures.

14. The system of claim 8, wherein the controller is in a sleep mode until receiving a pulse interrupt from the antenna via the high voltage induced on the conductor or receiving a timer interrupt internally triggered by the controller when a predetermined length of time elapses without the pulse interrupt being received by the controller from the antenna.

15. The system of claim 14, wherein the broad frequency pulse detector further comprises a coulomb counter or capacitor, wherein at least one of the broad frequency pulse detector and the controller is configured to determine a voltage reading of the high voltage induced down the conductor via output from the coulomb counter or the capacitor.

16. A method for monitoring a conductor of an electric fence, the method comprising:
detecting high voltage with an antenna spaced apart from and proximate to the conductor, wherein the antenna is positioned such that the high voltage on the conductor induces current flow on the antenna;
sending the current flow from the antenna to a controller;
determining with the controller that the current flow has stopped being induced on the antenna for a predetermined length of time;
indicating, via the controller to a communication device, that the conductor is off or inactive based on the determination that the current flow has stopped being induced on the antenna for the predetermined length of time; and
transmitting with the communication device a notification signal to at least one of a local notification device and a remote computing device that the conductor is off or inactive.

17. The method of claim 16, further comprising attaching a non-conductive housing supporting the antenna onto a structure supporting the conductor and actuating the antenna relative to the non-conductive housing until the antenna is directed toward the conductor.

18. The method of claim 16, further comprising grounding at least one of the controller and the communication device.

19. The method of claim 16, wherein the operation of determining with the controller the next high voltage pulse has not been received includes receiving a plurality of pulse interrupts from the antenna via the current induced on the antenna and then receiving a timer interrupt that is internally triggered by the controller in response to the predetermined length of time elapsing without the pulse interrupt being received by the controller from the antenna.

20. The method of claim 19, wherein the notification signal indicating that the conductor is off or inactive is transmitted by the communication device in response to the controller receiving the timer interrupt.
